(19) United States
(12) Patent Application Publication
(10) Pub. No.: US 2023/0253215 A1
(43) Pub. Date: Aug. 10, 2023

(54) METHOD FOR PRODUCING CIRCUIT BOARD

(71) Applicant: Resonac Corporation, Tokyo (JP)

(72) Inventors: Masaya TOBA, Tokyo (JP); Kazuhiko KURAFUCHI, Tokyo (JP); Takashi MASUKO, Tokyo (JP); Kazuyuki MITSUKURA, Tokyo (JP)

(21) Appl. No.: 18/017,954

(22) PCT Filed: Jul. 28, 2020
(86) PCT No.: PCT/JP2020/028925

§ 371 Date: Jan. 25, 2023

(51) Int. Cl. H01L 21/48; H01L 23/498; C25D 7/12; C25D 5/48; C25D 5/02; C23C 18/16; C23C 28/02

(52) U.S. Cl. CPC H01L 21/4857; H01L 23/49822; C25D 7/123; C25D 5/48; C25D 5/022; C23C 18/1653; C23C 28/023; C23C 18/38

(57) ABSTRACT

A method for producing a wiring board according to the present disclosure includes: (A) forming a first insulating material layer on a supporting substrate; (B) forming a first opening part in the first insulating material layer; (C) forming a seed layer on the first insulating material layer; (D) providing a resist pattern on a surface of the seed layer; (E) forming a wiring part including a pad and wiring; (F) removing the resist pattern; (G) removing the seed layer; (H) applying a first surface treatment to the surface of the pad; (I) forming a second insulating material layer; (J) forming a second opening part in the second insulating material layer; (K) applying a second surface treatment to the surface of the pad; and (L) heating the second insulating material layer to a temperature equal to or higher than the glass transition temperature of the second insulating material layer.

### TECHNICAL FIELD

The present disclosure relates to a method for producing a wiring board.

### BACKGROUND ART

For the purpose of achieving high density and high performance of semiconductor packages, a packaging form in which chips having different performances are mixedly mounted in a single package has been proposed, and a technology of high-density interconnection between chips, which is excellent in terms of cost, is considered important (see, for example, Patent Literature 1).

Package-on-package in which different packages are stacked on a package by flip-chip packaging to be connected, is widely employed in smartphones and tablet terminals (see, for example, Non-Patent Literatures 1 and 2). Regarding forms for packaging at a higher density, a packaging technology of using an organic substrate having a high-density wiring (organic interposer), a fan-out type packaging technology (FO-WLP) involving through mold vias (TMV), a packaging technology of using a silicon or glass interposer, a packaging technology of using through silicon vias (TSV), a packaging technology of using a chip embedded in a substrate for inter-chip transmission, and the like have been proposed. Particularly, in the organic interposer and FO-WLP, in the case of mounting semiconductor chips by arranging the semiconductor chips in parallel, a fine wiring layer is required for high-density electrical conduction (see, for example, Patent Literature 2).

### CITATION LIST

### Patent Literature

Patent Literature 1: Japanese Unexamined Patent Publication No. 2003-318519

Patent Literature 2: U.S. Patent Application Publication No. 2011/0221071

### Non Patent Literature

Non Patent Literature 1: Application of Through Mold Via (TMV) as PoP Base Package, Electronic Components and Technology Conference (ECTC), 2008

Non Patent Literature 2: Advanced Low Profile PoP Solution with Embedded Wafer Level PoP (eWLB-PoP) Technology, ECTC, 2012

### SUMMARY OF INVENTION

### Technical Problem

In the technology described in the above-described Patent Literature 1, after a desmear treatment, wiring is formed through steps of electroless plating, resist patterning, electrolytic plating, resist peeling, seed etching, and formation of an insulating material. In order to ensure close adhesion between the wiring and an insulating material, it is necessary to bring the wiring surface into a moderately rough state by etching or the like and firmly fix the insulating material to the wiring by an anchor effect.

However, in recent years, wiring boards are required to have a reduced transmission loss in a high-frequency band. As described above, when the wiring surface is roughened, the transmission loss is increased due to a skin effect. However, in a method for producing a wiring board, when an insulating material layer is formed without going through a step of roughening the wiring surface, there occurs another problem that the adhesiveness to the wiring surface is deteriorated, and thus the electrical insulation properties are deteriorated. Therefore, it is an object to produce a wiring board that shows excellent electrical insulation properties while securing adhesiveness between wiring and an insulating material.

Furthermore, even in a case where wiring and an insulating material closely adhere to each other immediately after wiring board assembling, a thick oxide layer (for example, CuO layer) is formed on the wiring surface by performing long-term heat resistance tests such as a high-temperature standing test, a moisture absorption resistance test, a reflow resistance test, and an acceleration test, and there occurs a problem that the adhesiveness to the insulating material is deteriorated. As a result, there occurs a problem that the electrical insulation properties are deteriorated. Incidentally, as an example of the acceleration test, HAST (Highly Accelerated Stress Test) may be mentioned.

The present disclosure was achieved in view of the above-described problems, and it is an object of the present disclosure to provide a method for producing a wiring board in which a wiring part and an insulating material layer have sufficient adhesiveness and heat resistance and also have sufficient insulation reliability.

### Solution to Problem

A method for producing a wiring board according to the present disclosure includes the following steps of:
(A) forming a first insulating material layer on a supporting substrate;
(B) forming a first opening part in the first insulating material layer;
(C) forming a seed layer on a surface of the first insulating material layer by electroless plating;
(D) providing a resist pattern for wiring part formation on a surface of the seed layer;
(E) forming a wiring part including a pad and wiring by electrolytic plating in a region exposed from the resist pattern on the surface of the seed layer;
(F) removing the resist pattern;
(G) removing the exposed seed layer by removal of the resist pattern;
(H) applying a first surface treatment to a surface of the wiring part;
(I) forming a second insulating material layer so as to cover the wiring part;
(J) forming a second opening part at a position corresponding to the pad in the second insulating material layer;
(K) applying a second surface treatment to the surface of the pad; and
(L) a heating the second insulating material layer to a temperature equal to or higher than the glass transition temperature of the second insulating material layer.

In the above-described step (H), the adhesiveness between the wiring part and the second insulating material layer can be improved by subjecting the surface of the wiring part to a treatment of improving the adhesiveness to the second insulating material layer (first surface treatment). As a specific example of the first surface treatment, a treatment of using a surface treatment agent including an organic component that improves the adhesiveness between a wiring part formed from a metal material and a second insulating material layer, may be mentioned. The average roughness Ra of the surface of the wiring part that has been subjected to the first surface treatment is, for example, 40 to 80 nm. By applying the first surface treatment to the surface of the wiring part, the adhesiveness between the wiring part and the second insulating material layer can be sufficiently increased even without excessively roughening the surface of the wiring part. After the step (J), the peel strength of the second insulating material layer is, for example, 0.2 to 0.7 kN/m with respect to the wiring. Furthermore, since the surface of the wiring part is not excessively rough, the transmission loss can be made sufficiently small. In the case of forming a fine wiring pattern on the first insulating layer, in the above-described step (D), for example, a resist pattern having groove-shaped openings having a line width of 0.5 to 20 μm may be formed.

According to the present disclosure, as a second surface treatment is applied to the surface of the pad in the above-described step (K), the pad can obtain excellent conductivity. That is, a surface-treated layer is formed on the surface of the pad by the first surface treatment of the above-described step (H), and even in a case where this layer lowers the conductivity of the pad, the conductivity of the pad can be restored by, for example, applying a treatment of removing this layer in the above-described step (K). Furthermore, according to the present disclosure, the adhesiveness of the wiring part and the second insulating material layer can be further improved by carrying out both the above-described step (H) and the above-described step (L), and a wiring board having excellent insulation reliability can be produced.

The above-described production method may further include a step of removing residue on the first insulating material layer and/or in the first opening part, between step (B) and step (C). The treatment of removing residue may be referred to as a desmear treatment. At least one of the first insulating material layer and the second insulating material layer may include a photosensitive resin. In a case where the insulating material layer includes a photosensitive resin, for example, an opening part can be formed by a photolithography process.

It is preferable that the second opening part is formed at a position corresponding to the pad. In this case, the above-described production method may further include a step of applying a second surface treatment to the surface of the pad inside the second opening part. In a case where a surface treatment agent including an organic component such as described above is used in the step of applying the first surface treatment, this surface treatment agent can be removed from the surface of the pad by the second surface treatment. The second surface treatment is at least one selected from the group consisting of, for example, an oxygen plasma treatment, an argon plasma treatment, and a desmear treatment.

### Advantageous Effects of Invention

According to the present disclosure, there is provided a method for producing a wiring board in which a wiring part and an insulating material layer have sufficient adhesiveness and heat resistance and also have sufficient insulation reliability.

### BRIEF DESCRIPTION OF DRAWINGS

FIG. 1A is a cross-sectional view schematically illustrating a state in which a first insulating material layer is formed on a supporting substrate, FIG. 1B is a cross-sectional view schematically illustrating a state in which a first opening part is provided on the first insulating material layer, FIG. 1C is a cross-sectional view schematically illustrating a state in which the first insulating material layer and the first opening part are subjected to a desmear treatment, and FIG. 1D is a cross-sectional view schematically illustrating a state in which a seed layer is formed on the first insulating material layer.

FIG. 2A is a cross-sectional view schematically illustrating a state in which a resist pattern for wiring part formation is formed on the seed layer, FIG. 2B is a cross-sectional view schematically illustrating a state in which a wiring part is formed by electrolytic plating, FIG. 2C is a cross-sectional view schematically illustrating a state in which the resist pattern has been removed, and FIG. 2D is a cross-sectional view schematically illustrating a state in which the seed layer exposed by removal of the resist pattern has been removed.

FIG. 3A is a cross-sectional view schematically illustrating a state in which the surface of the wiring part is subjected to a first surface treatment, FIG. 3B is a cross-sectional view schematically illustrating a state in which a second insulating material layer having a second opening part is formed on the first insulating material layer, and FIG. 3C is a cross-sectional view schematically illustrating a state in which the surface of the pad is subjected to a second surface treatment.

FIG. 4 is a cross-sectional view schematically illustrating a state in which a calcined layer is formed between the second insulating material layer and the wiring part by heating the second insulating material layer to a temperature equal to or higher than the glass transition temperature thereof.

FIG. 5 is a cross-sectional view schematically illustrating an embodiment of a wiring board having a multilayered wiring layer.

### DESCRIPTION OF EMBODIMENTS

Hereinafter, embodiments of the present disclosure will be described in detail with reference to the drawings. In the following description, identical or equivalent parts will be assigned with the same reference numeral, and any overlapping description will not be repeated. Furthermore, it should be noted that unless particularly stated otherwise, the positional relationship such as up, down, right, and left is based on the positional relationship shown in the drawings. The dimensional ratios of the drawings are not limited to the ratios shown therein.

When terms such as “left”, “right”, “front surface”, “back surface”, “up”, “down”, “upper”, and “lower” are utilized in the description and the claims of the present specification, these are intended to be illustrative and do not necessarily mean that the positions are permanently these relative positions. Furthermore, the term “layer” includes the structure of the shape formed over the entire surface as well as the structure of the shape formed in a portion, when viewed in a plan view. The term “A or B” may include either one of A and B, or may include both of them.

The term “step” as used in the present specification is not only an independent step, and even when the step cannot be clearly distinguished from other steps, the step is included in the present term as long as a predetermined action of the step is achieved. Furthermore, a numerical value range expressed by using the term “to” indicates a range that includes the numerical values described before and after the term “to” as the minimum value and the maximum value, respectively.

The content of each component in a composition according to the present specification means, in a case where a plurality of substances corresponding to each component is present in the composition, the total amount of the plurality of substances present in the composition, unless particularly stated otherwise. Furthermore, the exemplified substances may be used singly unless particularly stated otherwise, or two or more kinds thereof may be used in combination. Furthermore, with regard to a numerical value range described stepwise in the present specification, the upper limit value or lower limit value of a numerical value range of a certain stage may be replaced with the upper limit value or lower limit value of a numerical value range of another stage. Furthermore, with regard to a numerical value range described in the present specification, the upper limit value or lower limit value of the numerical value range may be replaced with a value shown in the Examples.

With reference to the drawings, a method for producing a wiring board according to embodiments of the present disclosure will be described. The method for producing a wiring board according to the present embodiment includes at least the following steps of:
(A) forming a first insulating material layer 1 on a supporting substrate S;
(B) forming a first opening part H1 in the first insulating material layer 1;
(C) forming a seed layer T on a surface of the first insulating material layer 1 by electroless plating;
(D) providing a resist pattern R for wiring part formation on a surface of a seed layer T;
(E) forming a wiring part C including a pad C1 and wiring C2 by electrolytic plating in a region exposed from the resist pattern R on the surface of the seed layer T;
(F) removing the resist pattern R;
(G) removing the exposed seed layer T by removal of the resist pattern R;
(H) applying a first surface treatment to a surface of the pad 1 and the wiring C2;
(I) forming a second insulating material layer 2 so as to cover the pad C1 and the wiring C2;
(J) forming a second opening part H2 in the second insulating material layer 2;
(K) applying a second surface treatment to a surface of the pad C1 inside the second opening part H2; and
(L) heating the second insulating material layer 2 to a temperature equal to or higher than the glass transition temperature of the second insulating material layer 2.

The wiring board according to the present embodiment is suitable for a form where micronization and multi-pinning are required, and the wiring board is suitable particularly for a package form in which an interposer for mixedly mounting different kinds of chips. More specifically, the production method according to the present embodiment is suitable for a package form in which the interval of pins is 200 μm or less (in a case of a finer wiring board, for example, 30 to 100 μm) and the number of pins is 500 or more (in a case of a finer wiring board, for example, 1000 to 10000 pins). Hereinafter, each step will be described.

### <Step of Forming First Insulating Material Layer on Supporting Substrate>

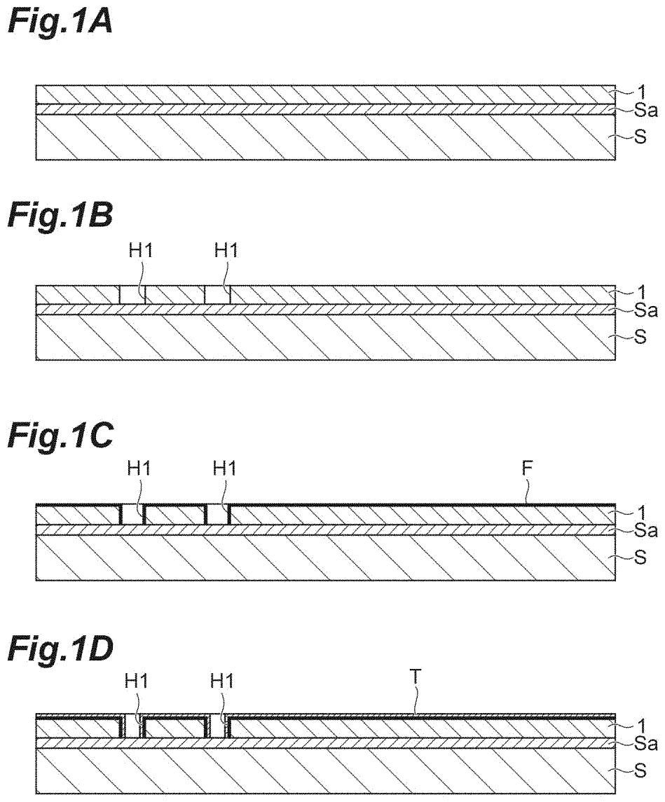

A first insulating material layer 1 is formed on a supporting substrate S (FIG. 1A). The supporting substrate S is not particularly limited; however, the supporting substrate S is a silicon plate, a glass plate, a SUS plate, a glass cloth-containing substrate, a semiconductor element-containing sealing resin, or the like, and a substrate having high rigidity is suitable. As shown in FIG. 1A, the supporting substrate S may be a substrate in which a conductive layer Sa is formed on the surface on the side where an insulating material layer is formed. The supporting substrate S may also be a substrate having wiring and/or a pad, instead of the conductive layer Sa, on the surface.

It is preferable that the thickness of the supporting substrate S is in the range of from 0.2 mm to 2.0 mm When the thickness is thinner than 0.2 mm, handling may be difficult, while when the thickness is thicker than 2.0 mm, the material cost tends to be high. The supporting substrate S may be in a wafer form or a panel form. The size is not particularly limited; however, a water having a diameter of 200 mm, a diameter of 300 mm, or a diameter of 450 mm, or a rectangular panel measuring 300 to 700 mm on one side is preferably used.

It is preferable that a photosensitive resin material is employed as a material constituting the first insulating material layer 1. The photosensitive insulating material may be in a liquid form or a film form, and from the viewpoints of the film thickness evenness and the cost, a film-shaped photosensitive insulating material is preferred. Furthermore, from the viewpoint that fine wiring can be formed, it is preferable that the photosensitive insulating material contains a filler (filler material) having an average particle size of 500 nm or less (more preferably 50 to 200 mn). The filler content of the photosensitive insulating material is preferably 0 to 70 parts by mass, and more preferably 10 to 50 parts by mass, with respect to 100 parts by mass of the mass of the photosensitive insulating material excluding the filler.

In the case of using a film-shaped photosensitive insulating material, it is preferable that a lamination step therefor is carried out at a temperature as low as possible, and it is preferable to employ a photosensitive insulating film that can be laminated at 40° C. to 120° C. A photosensitive insulating film having a temperature for enabling lamination of below 40° C. tends to have strong tackiness at normal temperature (about 25° C.) and deteriorated handleability, and a photosensitive insulating film having a temperature for enabling lamination of above 120° C. tends to have large warpage after lamination.

The coefficient of thermal expansion after curing of the first insulating material layer 1 is preferably 80×10⁻6/K or less from the viewpoint of suppressing warpage, and more preferably 70×10⁻⁶/K or less from the viewpoint of obtaining high reliability. Furthermore, from the viewpoint of obtaining stress relaxation properties of the insulating material and a high-definition pattern, the coefficient of thermal expansion is preferably 20×10⁻⁶/K or greater.

The thickness of the first insulating material layer 1 is preferably 10 μm or less, more preferably 5 μm or less, and even more preferably 3 μm or less. From the viewpoint of insulation reliability, it is preferable that the thickness of the first insulating material layer 1 is within the above-described range.

### <Step of Forming First Opening Part on Surface of First Insulating Material Layer>

A first opening part H1 that reaches to the supporting substrate S or a conductive layer Sa is formed on the surface of the first insulating material layer 1 (FIG. 1B). According to the present embodiment, the first opening part H1 is formed so as to penetrate through the first insulating material layer 1 in the thickness direction thereof and is composed of a bottom face (surface of the conductive layer Sa) and lateral faces (insulating material layer 1). When the first insulating material layer 1 is formed from a photosensitive resin material, the first opening part H1 can be formed by a photolithography process (exposure and development).

As a method for exposing the photosensitive resin material, an ordinary projection exposure method, a contact exposure method, a direct drawing exposure method, and the like can be used. As a developing method, it is preferable to use an alkali aqueous solution of sodium carbonate or TMAH (tetramethylammonium hydroxide). After the first opening part H1 is formed, the first insulating material layer may be further heated and cured. For example, the process is carried out at a heating temperature of 100° C. to 200° C. and a heating time of from 30 minutes to 3 hours.

The first opening part H1 may be formed in the first insulating material layer 1 according to a method other than photolithography process (for example, laser ablation, sand blasting, water blasting, or imprinting). For example, when the first insulating material layer 1 is formed from a thermosetting resin material, laser ablation is preferable from the viewpoint that the first opening part H1 can be formed. Regarding a method of forming an opening by laser ablation, an opening can be formed by means of a CO₂ laser, a UV-YAG laser, or the like; however, from the viewpoint of cost, a method of forming an opening using a CO₂ laser is preferable. Resin residue on the surface of the conductive layer Sa exposed from the first opening part H1 may be removed by a desmear treatment. The surface of the first insulating material layer 1 may also be roughened by this desmear treatment. The surface F shown in FIG. 1C represents a surface subjected to a desmear treatment.

### <Step of Forming Seed Layer on Surface of First Insulating Material Layer>

A seed layer T is formed on the surface of the first insulating material layer 1 by electroless plating (FIG. 1D). According to the present embodiment, first, in order to adsorb palladium that serves as a catalyst for electroless copper plating to the surface of the first insulating material layer 1, the surface of the first insulating material layer 1 is washed with a pretreatment liquid. The pretreatment liquid may be a commercially available alkaline pretreatment liquid including sodium hydroxide or potassium hydroxide. The concentration of sodium hydroxide or potassium hydroxide is set between 1% and 30%.

The time for immersion in the pretreatment liquid is set between 1 minute to 60 minutes. The temperature for immersion in the pretreatment liquid is set between 25° C. and 80° C. After the pretreatment, in order to remove any excess pretreatment liquid, the surface may be washed with tap water, pure water, ultrapure water, or an organic solvent. Incidentally, before the seed layer T is formed on the surface of the first insulating material layer 1, the surface of the first insulating material layer 1 may be modified by a method such as ultraviolet irradiation, electron beam irradiation, ozone water treatment, corona discharge treatment, or plasma treatment.

After the removal of the pretreatment liquid, in order to remove alkali ions from the surface of the first insulating material layer 1, the surface is subjected to immersion washing with an acidic aqueous solution. The acidic aqueous solution may be an aqueous solution of sulfuric acid, and the concentration is set between 1% and 20%, while the immersion time is set between 1 minute and 60 minutes. In order to remove the acidic aqueous solution, the surface may be washed with tap water, pure water, ultrapure water, or an organic solvent.

Subsequently, palladium is attached to the surface of the first insulating material layer 1 after immersion washing with an acidic aqueous solution is achieved. Regarding palladium, a commercially available palladium-tin colloid solution, an aqueous solution including palladium ions, a palladium ion suspension, or the like may be used; however, an aqueous solution including palladium ions that effectively adsorb to the modified layer is preferable.

When the surface is immersed in an aqueous solution including palladium ions, the temperature of the aqueous solution including palladium ions is set between 25° C. and 80° C., and the immersion time for adsorption is set between 1 minute and 60 minutes. After palladium ions are adsorbed, in order to remove excess palladium ions, the surface may be washed with tap water, pure water, ultrapure water, or an organic solvent.

After the adsorption of palladium ions, activation for causing palladium ions to act as a catalyst is carried out. The reagent for activating palladium ions may be a commercially available activating agent (activation treatment liquid). The temperature of the activating agent for immersing palladium ions to be activated is set between 25° C. and 80° C., and the time for immersing palladium ions to be activated is set between 1 minute to 60 minutes. After the activation of palladium ions, the surface may be washed with tap water, pure water, ultrapure water, or an organic solvent in order to remove excess activating agent.

Subsequently, the surface of the first insulating material layer 1 is subjected to electroless plating, and a seed layer T is formed. This seed layer T serves as a power supply layer for electrolytic plating. Examples of electroless copper plating include electroless pure copper plating (purity 99% by mass or higher) and electroless copper nickel phosphorus plating (nickel content percentage: 1% by mass to 10% by mass, phosphorus content: 1% by mass to 13% by mass); however, from the viewpoint of adhesiveness, electroless copper nickel phosphorus plating is preferable. The electroless copper nickel phosphorus plating liquid may be a commercially available plating liquid, and for example, an electroless copper nickel phosphorus plating liquid (manufactured by JCU CORPORATION, trade name “AISL-570”) can be used. Electroless copper nickel phosphorus plating is performed in an electroless copper nickel phosphorus plating liquid at 60° C. to 90° C. The thickness of the seed layer T is preferably 20 nm to 200 nm, more preferably 40 nm to 200 nm, and even more preferably 60 nm to 200 nm.

After electroless copper plating, the surface may be washed with tap water, pure water, ultrapure water, or an organic solvent in order to remove excess plating liquid. Furthermore, after the electroless copper plating, thermal curing (annealing: aging hardening treatment by heating) may be performed in order to increase the adhesion power between the seed layer T and the first insulating material layer 1. Regarding the thermal curing temperature, it is preferable to heat at 80° C. to 200° C. In order to further accelerate reactivity, it is more preferable to heat at 120° C. to 200° C., and it is even more preferable to heat at 120° C. to 180° C. The thermal curing time is preferably 5 minutes to 60 minutes, more preferably 10 minutes to 60 minutes, and even more preferably 20 minutes to 60 minutes.

### <Step of Forming Resist Pattern for Wiring Part Formation>

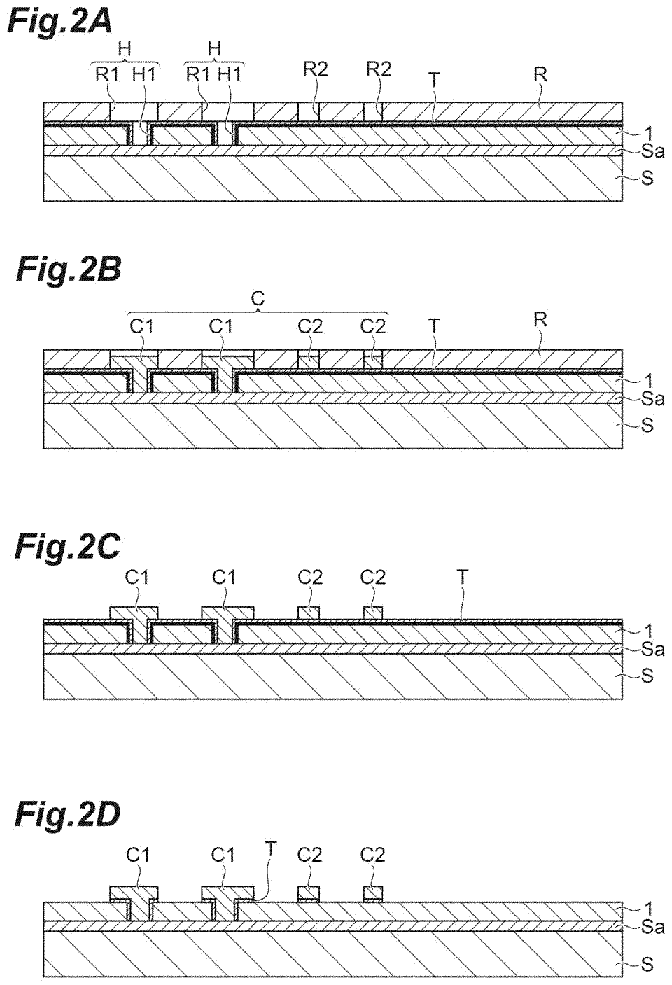

A resist pattern R for wiring part formation is formed on the seed layer T (FIG. 2A). The resist pattern R may be a commercially available resist, and for example, a negative-type film-shaped photosensitive resist (manufactured by Hitachi Chemical Company, Co., Ltd., Photec RY-5107UT) can be used. The resist pattern R has opening parts R1 and R2, as shown in FIG. 2A. An opening part R1 is provided at a position corresponding to the opening part H1 of the first insulating material layer 1 and is intended for forming a pad C1. An opening H is constructed by the first opening part H1 and the opening part R1. An opening part R2 is, for example, a groove-shaped opening having a line width of 0.5 to 20 μm and is intended for forming wiring C2.

The resist pattern R can be formed through the following steps. The resist pattern R can be formed by first forming a resist by using a roll laminator, subsequently closely adhering a photo-tool having a pattern formed thereon to the resist, performing exposure by using an exposure machine, and then performing spray development with an aqueous solution of sodium carbonate. Incidentally, a positive-type photosensitive resist may be used instead of a negative-type.

### <Step of Forming Wiring Part>

By using the seed layer T as a power supply layer, for example, electrolytic copper plating is performed, and a wiring part C including a pad C1 and wiring C2 is formed (FIG. 2B). The thickness of the wiring part C is preferably 1 to 10 μm, more preferably 3 to 10 μm, and even more preferably 5 to 10 μm. Incidentally, the wiring part C may be formed by electrolytic plating other than electrolytic copper plating.

### <Step of Removing Resist Pattern>

After the electrolytic copper plating, the resist pattern R is removed (FIG. 2C). Peeling of the resist pattern R may be carried out by using a commercially available peeling liquid.

### <Step of Removing Seed Layer>

After the resist pattern R is removed, the seed layer T is removed (FIG. 2D). Along with the removal of the seed layer T, palladium remaining under the seed layer T may also be removed. Removal of these may be carried out by using a commercially available removal liquid (etching liquid), and specific examples include acidic etching liquids (manufactured by JCU CORPORATION, BB-20, PJ-10, and SAC-700W3C).

### <Step of Applying First Surface Treatment to Surface of Pad C1 and Wiring C2>

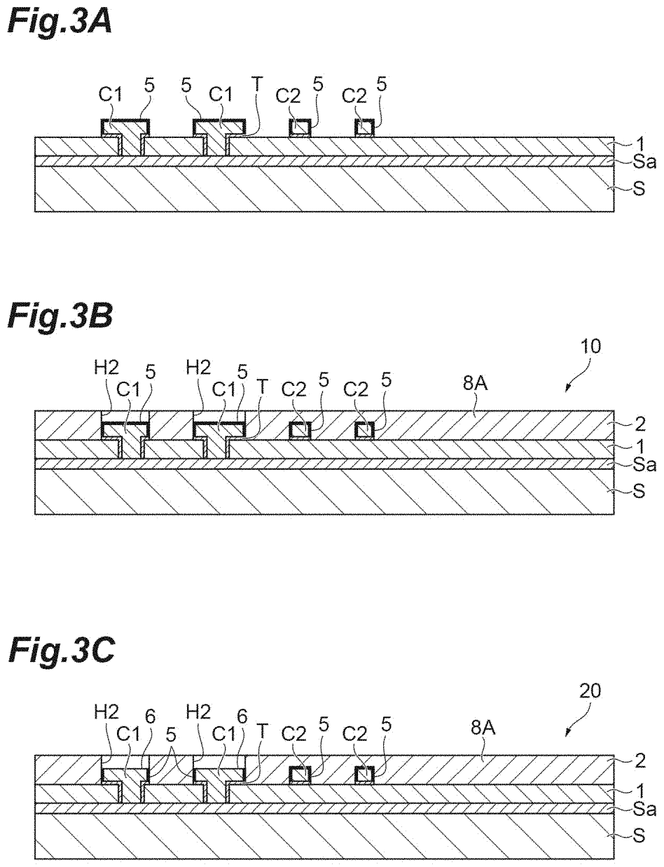

By applying a first surface treatment to the surface of the pad C1 and the wiring C2, a surface-treated layer 5, is formed on the surface of these (FIG. 3A). The first surface treatment can be performed by using a commercially available surface treatment liquid. As the surface treatment liquid, for example, a liquid including an organic component that improves adhesiveness between the wiring part C and a second insulating material layer 2 that is formed in the subsequent step (for example, manufactured by SHIKOKU CHEMICALS CORPORATION, trade name “GliCAP”), or a liquid including an organic component that finely etches the surface of the wiring part C and also improves the adhesiveness between the wiring part C and the second insulating material layer 2 (for example, manufactured by Atotech Japan Co., Ltd., trade name “NOVABOND”, and manufactured by MEC Co., Ltd., trade name “CZ8401” or “CZ-8402”) can be used.

The average roughness Ra of the surface of the wiring part C (pad C1 and wiring C2) after being subjected to the first surface treatment is, for example, 40 to 80 nm, and the average roughness Ra may be 50 to 80 nm or 60 to 80 nm. When the average roughness Ra of the surface of the wiring part C is 40 nm or more, the adhesiveness between the wiring part C and the second insulating material layer 2 can be sufficiently secured, and when the average roughness Ra is 80 nm or less, the transmission loss of the wiring board can be made sufficiently small.

### <Step of Forming Second Insulating Material Layer>

A second insulating material layer 2 is formed so as to cover the wiring part C. The material constituting the second insulating material layer 2 may be identical with or different from the material of the first insulating material layer.

### <Step of Forming Second Opening Part in Second Insulating Material Layer>

A second opening part H2 is formed in the second insulating material layer 2 (FIG. 3B). The second opening part H2 is provided at a position corresponding to the pad C1. A method for forming the second opening part H2 may be identical with or different from the method of forming the first opening part H1. After this step, the peel strength of the second insulating material layer 2 is, for example, 0.2 to 0.7 kN/m with respect to the wiring C2, and the peel strength may be 0.4 to 0.65 kN/m or 0.5 to 0.6 kN/m. The peel strength as used herein means a value measured under the conditions of a peeling angle of 90° and a peeling rate of 10 mm/min. Through these steps, the wiring board 10 shown in FIG. 3B is obtained. The wiring board 10 includes a supporting substrate S, a pad C1 provided so as to penetrate through a first insulating material layer 1 and a second insulating material layer 2, and a wiring layer 8A having wiring C2 embedded in the second insulating material layer 2.

### <Step of Applying Second Surface Treatment to Surface of Pad>

A surface-treated layer 5, is removed by applying a second surface treatment to the surface of the pad C1 inside the second opening part H2 (FIG. 3C). As described above, the surface-treated layer 5 contains, for example, an organic component and can inhibit the conductivity of the pad C1. By removing at least a portion of the surface-treated layer 5, that is, by providing a surface treatment agent-removed part 6 on the surface of the pad C1 as shown in FIG. 3C, a decrease in the conductivity of the pad C1 by the surface-treated layer 5 can be ameliorated. As a treatment for removing the surface-treated layer 5, for example, a plasma treatment and a desmear treatment (treatment of using an alkali solution) may be mentioned. The type of the gas used for the plasma treatment is, for example, oxygen, argon, nitrogen, and a mixed gas of these. A wiring board 20 having the configuration shown in FIG. 3C is obtained through this step. The wiring board 20 is different from the wiring board 10 shown in FIG. 3B from the viewpoint that the surface treatment agent-removed part 6 on the surface of the pad C1.

### <Step of Heating Second Insulating Material Layer>

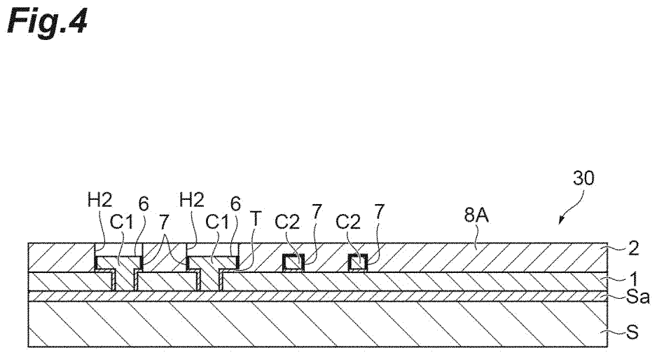

A calcined layer 7 is formed at the interface between the wiring part C and the second insulating material layer 2 by heating the second insulating material layer 2 to a temperature equal to or higher than the glass transition temperature (Tg) of the second insulating material layer 2 (FIG. 4). As a result, the adhesiveness of the wiring part C and the second insulating material layer 2 is further improved. The calcined layer 7 is, for example, a layer formed as the surface treatment agent included in the surface-treated layer 5, is degenerated by a reaction with the second insulating material layer 2. The heating temperature is equal to or higher than the glass transition temperature (Tg) of the second insulating material layer 2, and for example, the heating temperature is 250° C. or lower. The heating time is preferably 30 minutes to 3 hours. When the heating temperature is Tg or higher and the heating time is 30 minutes or more, an effect of improving the adhesiveness between the wiring part C and the second insulating material layer 2 is sufficiently exhibited. On the other hand, when the heating temperature is 250° C. or lower and the heating time is 3 hours or less, decomposition of the surface treatment agent remaining between the wiring part C and the second insulating material layer 2 is suppressed, and the wiring part C and the second insulating material layer 2 can maintain excellent adhesiveness. Furthermore, as the heating temperature is 250° C. or lower, warpage of the wiring board can be suppressed. Through this configuration, a wiring board 30 having the configuration shown in FIG. 4 is obtained. The wiring board 30 is different from the wiring board 20 shown in FIG. 3C from the viewpoint that a calcined layer 7 is formed at the interface between the wiring part C and the second insulating material layer 2.

Incidentally, the glass transition temperature of the second insulating material layer as used herein is the mid-point glass transition temperature value obtainable when the second insulating material layer after curing is measured using differential scanning calorimetry (DSC, for example, “Thermo Plus 2” manufactured by Rigaku Corp.). Specifically, the above-described glass transition temperature is a mid-point glass transition temperature obtained by measuring the changes in heat quantity under the conditions of a temperature increase rate of 10° C./min and a measurement temperature of 30° C. to 250° C. and calculating the temperature according to a method equivalent to JIS K 7121:1987.

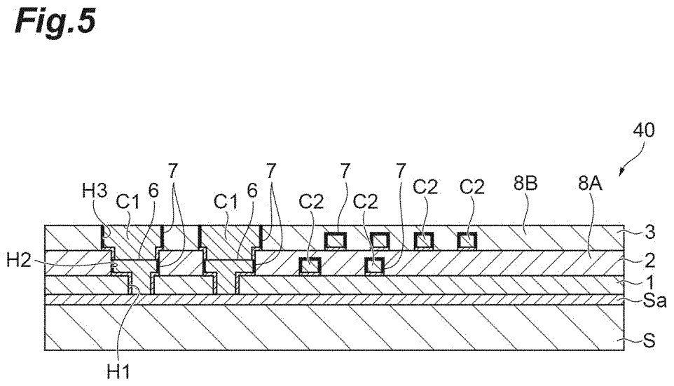

Thus, an embodiment of the method for producing a wiring board has been described; however, the present invention is not necessarily limited to the above-described embodiment, and modifications may be appropriately carried out to the extent that the gist of the invention is maintained. For example, in the above-described embodiment, a method for producing a wiring board further having a wiring layer 8A has been illustrated; however, a wiring board having a multilayered wiring layer may be produced. The multilayer wiring board 40 shown in FIG. 5 includes, in addition to the configuration of the wiring board 30, a third insulating material layer 3 and a wiring layer 8B composed of a wiring C2 embedded in this third insulating material layer 3. The pad C1 of the multilayer wiring board 40 is provided so as to penetrate through the first insulating material layer 1, the second insulating material layer 2, and the third insulating material layer 3.

### EXAMPLES

The present disclosure will be described in more detail by way of the following Examples; however, the present invention is not intended to be limited to these examples.

### Example 1

### <Production of Photosensitive Resin Film>

A photosensitive resin composition to be used for forming an insulating material layer was prepared by using the following components.

Photosensitive resin containing a carboxyl group and an ethylenically unsaturated group: Acid-modified cresol novolac type epoxy acrylate (CCR-1219H, manufactured by Nippon Kayaku Co., Ltd., trade name) 50 parts by mass

Photopolymerization initiator component: 2,4,6-Trimethylbenzoyl-diphenyl-phosphine oxide (DAROCUR TPO, manufactured by BASF Japan Ltd., trade name) and ethanone, 1-[9-ethyl-6-(2-methylbenzoyl)-9H-carbazol-3-yl]-, 1-(o-acetyloxime) (IRGACURE OXE-02, manufactured by BASF Japan Ltd., trade name) 5 parts by mass

Thermal curing agent component: Biphenol type epoxy resin (YX-4000, manufactured by Mitsubishi Chemical Corp., trade name) 10 parts by mass

Inorganic filler component; (average particle size: 50 mn, silane coupling-treated with vinylsilane)

The inorganic filler component was blended so as to have a content of 10 parts by volume with respect to 100 parts by volume of the resin content. Incidentally, the particle size distribution was measured by using a dynamic light scattering type NanoTrac particle size distribution meter “UPA-EX150” (manufactured by NIKKISO CO., LTD.) and a laser diffraction scattering type MicroTrac particle size distribution meter “MT-3100” (manufactured by NIKKISO CO., LTD.), and it was confirmed that the maximum particle size was 1 μm or less.

A solution of the photosensitive resin composition having the above-described composition was applied on the surface of a polyethylene terephthalate film (G2-16, manufactured by TEIJIN LIMITED, trade name, thickness: 16 μm). That solution was dried at 100° C. for about 10 minutes by using a hot air convection type dryer. The thickness of a photosensitive resin film formed by this process was 10 μm.

### <Formation of Wiring Layer Having Fine Wiring>

A glass cloth-containing wiring board (size: 200 mm on each side, thickness 1.5 mm) was prepared as a supporting substrate. A copper layer was formed on the surface of this wiring board, and the thickness of the copper layer was 20 μm.

Step (A)

On the surface of the copper layer of the wiring board, the above-described photosensitive resin film (first insulating material layer) was laminated. More particularly, first, the photosensitive resin film was placed on the surface of the copper layer of the wiring board. Next, the assembly was pressed by using a press type vacuum laminator (MVLP-500, manufactured by MEIKI & Company., LTD). The pressing conditions were set to a pressing hot plate temperature of 80° C., a vacuum drawing time of 20 seconds, a lamination press time of 60 seconds, an air pressure of 4 kPa or less, and a pressure-bonding pressure of 0.4 MPa.

Step (B)

An opening part (first opening part) reaching to the copper layer of the wiring board was provided in the first insulating material layer by subjecting the insulating material layer after pressing to exposure processing and development processing. Regarding exposure, a photo-tool having a pattern formed thereon was closely adhered onto the insulating material layer, and exposure was performed with an energy amount of 30 mJ/cm² by using an i-line stepper exposure machine (product name: S6CK type exposure machine, lens: ASC3(Ck), manufactured by CERMA PRECISION, INC.). Next, spray development was performed for 45 seconds with a 1 mass % aqueous solution of sodium carbonate at 30° C., and an opening part was provided. Next, the surface of the insulating material layer after development was subjected to post-UV exposure with an energy amount of 2000 mJ/cm² by using a mask exposure machine (EXM-1201 type exposure machine, manufactured by ORC MANUFACTURING CO., LTD.). Next, thermal curing was performed in a clean oven at 170° C. for 1 hour.

Step (C)

A seed layer was formed on the surface of the insulating material layer by electroless copper plating. That is, first, as alkali cleaning, the wiring board was immersed in a 110 mL/L aqueous solution of an alkali cleaner (manufactured by JCU CORPORATION, trade name: EC-B) at 50° C. for 5 minutes and then was immersed in pure water for 1 minute. Next, as a conditioner, the wiring board was immersed in a mixed liquid of a conditioning liquid (manufactured by JCU CORPORATION, trade name: PB-200) and EC-B (PB-200 concentration: 70 mL/L, EC-B concentration: 2 mL/L) at 50° C. for 5 minutes and then was immersed in pure water for 1 minute. Next, as soft etching, the wiring board was immersed in a mixed liquid of a soft etching liquid (manufactured by JCU CORPORATION, trade name: PB-228) and 98% sulfuric acid (PB-228 concentration: 100 g/L, sulfuric acid concentration: 50 mL/L) at 30° C. for 2 minutes, and then was immersed in pure water for 1 minute. Next, as a desmut, the wiring board was immersed in 10% sulfuric acid at room temperature for 1 minute. Next, as a catalyzer, the wiring board was immersed in a mixed liquid of reagent 1 for catalyzation (manufactured by JCU CORPORATION, trade name: PC-BA) and reagent 2 for catalyzation (manufactured by JCU CORPORATION, trade name: PB-333) (PC-BA concentration: 5 g/L, PB-333 concentration: 40 mL/L, EC-B concentration: 9 mL/L) at 60° C. for 5 minutes and was then immersed in pure water for 1 minute. Next, as an accelerator, the wiring board was immersed in a mixed liquid of a reagent for accelerator (manufactured by JCU CORPORATION, trade name: PC-66H) and PC-BA (PC-66H concentration: 10 mL/L, PC-BA concentration: 5 g/L) at 30° C. for 5 minutes, and then was immersed in pure water for 1 minute. Next, as electroless copper plating, the wiring board was immersed in a mixed liquid of an electroless copper plating liquid (manufactured by JCU CORPORATION, trade name: AISL-570B, AISL-570C, AISL-570MU) and PC-BA (AISL-570B concentration: 70 mL/L, AISL-570C concentration: 24 mL/L, AISL-570MU concentration: 50 mL/L, PC-BA concentration: 13 g/L) at 60° C. for 7 minutes and then was immersed in pure water for 1 minute. Subsequently, the wiring board was dried on a hot plate at 85° C. for 5 minutes. Next, the wiring board was subjected to thermal annealing in an oven at 180° C. for 1 hour.

Step (D)

On a substrate having a thickness of 200 mm and having an electroless copper film formed thereon, a resist for wiring formation (manufactured by Hitachi Chemical Company, Ltd., RY-5107UT) was vacuum laminated by using a vacuum laminator (manufactured by Nichigo-Morton Co., Ltd., V-160). The lamination temperature was 110° C., the lamination time was 60 seconds, and the lamination pressure was 0.5 MPa.

After vacuum lamination, the wiring board was left to stand for one day, and the resist for wiring formation was exposed by using an i-line stepper exposure machine (product name: S6CK type exposure machine, lens: ASC3(Ck), manufactured by CERMA PRECISION, INC.). The exposure amount was 140 mJ/cm², nd the focus was −15 μm. After exposure, the wiring board was left to stand for one day, a protective film of the resist for wiring formation was peeled off, and development was performed by using a spray developing machine (manufactured by Mikasa Co., Ltd., AD-3000). The liquid developer was a 1.0% aqueous solution of sodium carbonate, the development temperature was 30° C., and the spray pressure was 0.14 MPa. As a result, a resist pattern for forming a wiring with the following L/S (line/space) was formed on the seed layer.

L/S=20 μm/20 μm (number of wirings: 10 lines)

L/S=15 μm/15 μm (number of wirings: 10 lines)

L/S=10 μm/10 μm (number of wirings: 10 lines)

L/S=7 μm/7 μm (number of wirings: 10 lines)

L/S=5 μm/5 μm (number of wirings: 10 lines)

L/S=3 μm/3 μm (number of wirings: 10 lines)

L/S=2 μm/2 μm (number of wirings: 10 lines)

Step (E)

The wiring board was immersed in a 100 mL/L aqueous solution of a cleaner (manufactured by OKUNO Chemical Industries Co., Ltd., trade name: ICP CLEAN S-135) at 50° C. for 1 minute, immersed in pure water at 50° C. for 1 minute, immersed in pure water at 25° C. for 1 minute, and immersed in a 10% aqueous solution of sulfuric acid at 25° C. for 1 minute. Next, the wiring board was subjected to electrolytic plating in an aqueous solution obtained by adding 0.25 mL of hydrochloric acid, 10 mL of trade name: TOP LUCINA GT-3 manufactured by OKUNO Chemical Industries Co., Ltd., and 1 mL of trade name TOP LUCINA GT-2 manufactured by OKUNO Chemical Industries Co., Ltd. to 7.3 L of an aqueous solution of 120 g/L of copper sulfate pentahydrate and 220 g/L of 96% sulfuric acid, under the conditions of a current density of 1.5 A/dm² at 25° C. for 10 minutes. Subsequently, the wiring board was immersed in pure water at 25° C. for 5 minutes and was dried on a hot plate at 80° C. for 5 minutes.

Step (F)

The resist for wiring formation was peeled off by using a spray developing machine (manufactured by Mikasa Co., Ltd., AD-3000). The stripping liquid was a 2.38% aqueous solution of TMAH, the peeling temperature was 40° C., and the spray pressure was 0.2 MPa.

Step (G)

The electroless copper as the seed layer and the palladium catalyst were removed. As etching of electroless Cu, the wiring board was immersed in an etching liquid (manufactured by JCU CORPORATION, SAC-700W3C), 98% sulfuric acid, and an aqueous solution of 35% aqueous hydrogen peroxide and copper sulfate pentahydrate (SAC-700W3C concentration: 5% by volume, sulfuric acid concentration: 4% by volume, hydrogen peroxide concentration: 5% by volume, copper sulfate pentahydrate concentration: 30 g/L) at 35° C. for 1 minute. Next, as the removal of the palladium catalyst, the wiring board was immersed in an aqueous FL solution (manufactured by JCU CORPORATION, FL-A 500 mL/L, FL-B 40 mL/L) at 50° C. for 1 minute. Subsequently, the wiring board was immersed in pure water at 25° C. for 5 minutes and dried on a hot plate at 80° C. for 5 minutes.

Step (H)

The surfaces of the pad and the wiring were subjected to a surface treatment (first surface treatment) by using GliCAP (manufactured by SHIKOKU CHEMICALS CORPORATION). As acid washing, the wiring board was immersed in a 3.5% aqueous solution of hydrochloric acid at 25° C. for 1 minute. Next, the wiring board was washed with flowing water by using pure water at 25° C. for 1 minute. Next, the wiring board was immersed in a soft etching liquid (manufactured by SHIKOKU CHEMICALS CORPORATION, GB-1000) at 30° C. for 1 minute. Next, the wiring board was washed with flowing water by using pure water at 25° C. for 1 minute. Next, the wiring board was immersed in a surface treatment agent (manufactured by SHIKOKU CHEMICALS CORPORATION, GliCAP) at 30° C. for 15 minutes. Next, the wiring board was washed with flowing water by using pure water at 25° C. for 1 minute. Subsequently, the wiring board was dried on a hot plate at 100° C. for 5 minutes.

Step (I)

A photosensitive resin film (second insulating material layer) was laminated so as to cover the pad and wiring that had been surface-treated through step (H). More particularly, first, a photosensitive resin film was placed on the first insulating material layer so as to cover the pad and wiring. Next, the assembly was pressed by using a press type vacuum laminator (MVLP-500, manufactured by MEIKI & Company., LTD). The pressing conditions were set to a pressing hot plate temperature of 80° C., a vacuum drawing time of 20 seconds, a lamination press time of 60 seconds, an air pressure of 4 kPa or less, and a pressure-bonding pressure of 0.4 MPa.

Step (J)

An opening part (second opening part) reaching to the pad was provided in the second insulating material layer by subjecting the insulating material layer after pressing to exposure processing and development processing. Regarding exposure, a photo-tool having a pattern formed thereon was closely adhered onto the insulating material layer, and exposure was performed with an energy amount of 30 mJ/cm² by using an i-line stepper exposure machine (product name: S6CK type exposure machine, lens: ASC3(Ck), manufactured by CERMA PRECISION, INC.). Next, spray development was performed for 45 seconds with a 1 mass % aqueous solution of sodium carbonate at 30° C., and an opening was provided. Next, the surface of the insulating material layer after development was subjected to post-UV exposure with an energy amount of 2000 mJ/cm² by using a mask exposure machine (EXM-1201 type exposure machine, manufactured by ORC MANUFACTURING CO., LTD.). Next, thermal curing was performed in a clean oven at 170° C. for 1 hour. The glass transition temperature (Tg) of the second insulating material layer after curing was 160° C.

### Example 2

A wiring board was obtained in the same manner as in Example 1, except that surface treatment was performed in step (H) by using NOVABOND (manufactured by Atotech Japan Co., Ltd.) instead of GliCAP. That is, first, the wiring board was immersed in 15 mL/L of an aqueous solution of NOVABOND IT STABILIZER (manufactured by Atotech Japan Co., Ltd.) at 50° C. for 1 minute. Next, the wiring board was washed with flowing water by using pure water at 25° C. for 1 minute. Next, the wiring board was immersed in 30 mL/L of an aqueous solution of NOVABOND IT (manufactured by Atotech Japan Co., Ltd.) at 50° C. for 1 minute. Next, the wiring board was washed with flowing water by using pure water at 25° C. for 1 minute. Next, the wiring board was immersed in 20 mL/L of an aqueous solution of NOVABOND IT REDUCER (manufactured by Atotech Japan Co., Ltd.) at 30° C. for 5 minutes. Next, the wiring board was washed with flowing water by using pure water at 25° C. for 1 minute. Next, the wiring board was immersed in 10 mL/L of an aqueous solution of NOVABOND IT PROTECTOR MK (manufactured by Atotech Japan Co., Ltd.) at 35° C. for 1 minute. Next, the wiring board was washed with flowing water by using pure water at 25° C. for 1 minute. Subsequently, the wiring board was dried on a hot plate at 100° C. for 5 minutes.

### Example 3

A wiring board was obtained in the same manner as in Example 1, except that surface treatment was performed in step (H) by using CZ8401 (manufactured by MEC Co., Ltd.) instead of GliCAP. That is, first, as acid washing, the wiring board was spray-washed by using a 5% aqueous solution of hydrochloric acid at 25° C. for 30 seconds at a water pressure of 0.2 MPa. Next, the wiring board was washed with flowing water by using pure water at 25° C. for 1 minute. Next, the wiring board was subjected to a spray treatment by using a CZ8401 treatment liquid at 25° C. for 1 minute at a water pressure of 0.2 MPa. Next, the wiring board was washed with flowing water by using pure water at 25° C. for 1 minute. Next, the wiring board was subjected to a spray treatment by using a 10% aqueous solution of sulfuric acid at 25° C. for 20 seconds at a water pressure of 0.1 MPa. Next, the wiring board was washed with flowing water by using pure water at 25° C. for 1 minute. Subsequently, the wiring board was dried on a hot plate at 100° C. for 5 minutes.

### Example 4

A wiring board was obtained in the same manner as in Example 1, except that surface treatment was performed in step (H) by using CZ8402 (manufactured by MEC Co., Ltd.) instead of GliCAP. That is, first, as acid washing, the wiring board was spray-washed by using a 5% aqueous solution of hydrochloric acid at 25° C. for 30 seconds at a water pressure of 0.2 MPa. Next, the wiring board was washed with flowing water by using pure water at 25° C. for 1 minute. Next, the wiring board was subjected to a spray treatment by using a CZ8402 treatment liquid at 25° C. for 1 minute at a water pressure of 0.2 MPa. Next, the wiring board was washed with flowing water by using pure water at 25° C. for 1 minute. Next, the wiring board was subjected to a spray treatment by using a 10% aqueous solution of sulfuric acid at 25° C. for seconds at a water pressure of 0.1 MPa. Next, the wiring board was washed with flowing water by using pure water at 25° C. for 1 minute. Subsequently, the wiring board was dried on a hot plate at 100° C. for 5 minutes.

### Comparative Example 1

A wiring board was obtained in the same manner as in Example 1, except that a surface treatment agent was not used in step (H). That is, first, as acid washing, the wiring board was spray-washed by using a 5% aqueous solution of hydrochloric acid at 25° C. for 30 seconds at a water pressure of 0.2 MPa. Next, the wiring board was washed with flowing water by using pure water at 25° C. for 1 minute. Subsequently, the wiring board was dried on a hot plate at 100° C. for 5 minutes.

### Comparative Example 2

A wiring board was obtained in the same manner as in Example 1, except that surface treatment was performed in step (H) by using CZ8101 (manufactured by MEC Co., Ltd.) instead of GliCAP. That is, first, as acid washing, the wiring board was spray-washed by using a 5% aqueous solution of hydrochloric acid at 25° C. for 30 seconds at a water pressure of 0.2 MPa. Next, the wiring board was washed with flowing water by using pure water at 25° C. for 1 minute. Next, the wiring board was subjected to a spray treatment by using a CZ8101 treatment liquid at 25° C. for 1 minute at a water pressure of 0.2 MPa. Next, the wiring board was washed with flowing water by using pure water at 25° C. for 1 minute. Next, the wiring board was subjected to a spray treatment by using a 10% aqueous solution of sulfuric acid at 25° C. for 20 seconds at a water pressure of 0.1 MPa. Next, the wiring board was washed with flowing water by using pure water at 25° C. for 1 minute. Next, as a rust prevention treatment, the wiring board was subjected to an immersion treatment by using a CL-8300 (manufactured by MEC Co., Ltd.) treatment liquid at 25° C. for 30 seconds. Subsequently, the wiring board was dried on a hot plate at 100° C. for 5 minutes.

### <Measurement of Average Roughness Ra of Copper Layer Surface>

The average roughness Ra of the copper layer surface according to each of Example 1 (surface treatment using Glicap), Example 2 (surface treatment using NOVABOND), Example 3 (surface treatment using CZ-8401), Example 4 (surface treatment using CZ-8402), Comparative Example 1 (no surface treatment agent), and Comparative Example 2 (CZ-8101) was measured by using a surface roughness meter (manufactured by Olympus Corporation, OLS-4000). The results are shown in Table 1.

### <Measurement of Peel Strength of Interface Between Copper Layer and Insulating Material Layer>

The peel strength of the interface between the copper layer and the insulating material layer according to each of Example 1 (surface treatment using Glicap), Example 2 (surface treatment using NOVABOND), Example 3 (surface treatment using CZ-8401), Example 4 (surface treatment using CZ-8402), Comparative Example 1 (no surface treatment agent), and Comparative Example 2 (CZ-8101) was measured by using a peel strength measuring apparatus (manufactured by SHIMADZU CORPORATION, ES-Z). The measurement conditions were set to a peeling angle of 90° and a peeling rate of 10 mm/min. The results are shown in Table 1.

### <Evaluation of Wiring Forming Properties>

With regard to the wiring forming properties with L/S of 20 μm/20 μm, 15 μm/15 μm, 10μm/10 μm, 7 μm/7 μm, 5 μm/5 μm, 3 μm/3 μm, and 2μm/2 μm, among ten wirings, a case in which wiring collapse or wiring detachment, or wiring disconnection occurred in zero (0) wiring was rated as “A”; a case in which the above-described defect occurred in 1 to 2 wirings was rated as “B”; and a case in which the above-described defect occurred in 3 or more wirings was rated as “C”. The results are shown in Table 1.

TABLE 1

| | Average | | | | | | | |
|---|---|---|---|---|---|---|---|---|
| | roughness Ra | | | | | | | |
| | of copper | Peel | Evaluation of wiring | | | | | |
| | layer surface | strength | forming properties(μm/μm) | | | | | |
| | (nm) | (kN/m) | 20/20 | 15/15 | 10/10 | 5/5 | 3/3 | 2/2 |
| Example 1 | 43.00 | 0.52 | A | A | A | A | A | A |
| Example 2 | 45.00 | 0.75 | A | A | A | A | A | A |
| Example 3 | 65.00 | 0.67 | A | A | A | A | A | A |
| Example 4 | 67.00 | 0.62 | A | A | A | A | A | A |
| Comparative | 45.00 | 0.10 | A | A | A | A | A | A |
| Example 1 | | | | | | | | |
| Comparative | 400.00 | 0.72 | A | A | A | A | B | C |
| Example 2 | | | | | | | | |

Step (K)

The pad surfaces of the wiring boards according to Examples 1 to 4 and Comparative Examples 1 and 2 were subjected to a desmear treatment (second surface treatment). That is, first, for a swelling treatment, each of the wiring boards was immersed in 40 mL/L of a sweller (manufactured by Atotech, CLEANER SECURIGANTH 902) at 70° C. for 5 minutes. Subsequently, the wiring board was immersed in pure water for 1 minute. Next, in order to remove the surface treatment agent, the wiring board was immersed in 40 mL/L of a desmear liquid (manufactured by Atotech, COMPACT CP) at 70° C. The immersion time was set to 3 minutes. Next, the wiring board was immersed in pure water for 1 minute. Subsequently, the wiring board was dried on a hot plate at 80° C. for 5 minutes.

### <Evaluation of Surface Treatment Agent Removability>

The surface treatment agent removability according to Examples 1 to 4 and Comparative Examples 1 and 2 was evaluated. In opening parts of Φ100 μm, Φ50 μm, Φ30μm, χ20 μm, and Φ10 μm, the presence or absence of a peak at 900 cm⁻¹ at the exposed copper surface was examined by using a micro-Raman apparatus (product name: DXR2 Microscope, manufactured by Thermo Fisher Scientific Inc.), and among ten pads, a case in which the peak was observed (there was residue) in zero (0) pads was rated as “A”; a case in which the peak was observed in 1 to 2 pads was rated as “B”; while a case in which the peak was observed in 3 or more pads was rated as “C”. The results are presented in Table 2.

TABLE 2

| | | Diameter of pad opening part (μm) | | | | |
|---|---|---|---|---|---|---|
| | | 100 | 50 | 30 | 20 | 10 |
| Evaluation of | Example 1 | A | A | A | A | A |
| surface treatment | Example 2 | A | A | A | A | A |
| agent removability | Example 3 | A | A | A | A | A |
| | Example 4 | A | A | A | A | A |
| | Comparative | A | A | A | A | A |
| | Example 1 | | | | | |
| | Comparative | C | C | C | C | C |
| | Example 2 | | | | | |

### Examples 1a to 4d and Comparative Examples 1a to 2d

Step (L)

A plurality of wiring boards according to Examples 1 to 4 and Comparative Examples 1 and 2 were prepared, and as shown in Table 3, each of the wiring boards was heated at 200° C. or 250° C. for 30 minutes or 3 hours.

### <Evaluation of Electrical Insulation Properties>

The electrical insulation properties of the wiring boards according to Examples 1a to 4d and Comparative Examples 1a to 2d were evaluated. For wirings with L/S of 20 μm/20 μm, 15 μm/15 μm, 10 μm/10 μm, 7 μm/7 μm, 5 μm/5 μm, 3 μm/3 μm, and 2 μm/2 μm, the electrical insulation properties were tested by using a HAST chamber (EHS-222MD, manufactured by ESPEC CORP.) and an ion migration evaluation system (AM-150-U-5, manufactured by ESPEC CORP.) under the conditions of 130° C., a relative humidity of 85%, and an applied voltage of 3.3 V. Among ten wirings, a case in which the number of wirings with an electrical resistance value of 1×10⁶ Ω and an insulation retention time of 200 hours or longer was 10 was rated as “A”; a case in which the number of wirings with the above-described characteristics was 7 or more was rated as “B”; and a case in which the number of wirings with the above-described characteristics was 5 or more was rated as “C”. The results are presented in Table 3.

TABLE 3

| | Heating | Heating | Evaluation of electrical | | | | | | |
|---|---|---|---|---|---|---|---|---|---|
| | Temperature | Time | insulation properties L/S(μm/μm) | | | | | | |
| | (° C.) | (h) | 20/20 | 15/15 | 10/10 | 7/7 | 5/5 | 3/3 | 2/2 |
| Example 1a | 200 | 0.5 | A | A | A | A | A | A | A |
| Example 1b | 200 | 3.0 | A | A | A | A | A | A | A |
| Example 1c | 250 | 0.5 | A | A | A | A | A | A | A |
| Example 1d | 250 | 3.0 | A | A | A | A | A | A | A |
| Example 2a | 200 | 0.5 | A | A | A | A | A | A | A |
| Example 2b | 200 | 3.0 | A | A | A | A | A | A | A |
| Example 2c | 250 | 0.5 | A | A | A | A | A | A | A |
| Example 2d | 250 | 3.0 | A | A | A | A | A | A | A |
| Example 3a | 200 | 0.5 | A | A | A | A | A | A | A |
| Example 3b | 200 | 3.0 | A | A | A | A | A | A | A |
| Example 3c | 250 | 0.5 | A | A | A | A | A | A | A |
| Example 3d | 250 | 3.0 | A | A | A | A | A | A | A |
| Example 4a | 200 | 0.5 | A | A | A | A | A | A | A |
| Example 4b | 200 | 3.0 | A | A | A | A | A | A | A |
| Example 4c | 250 | 0.5 | A | A | A | A | A | A | A |
| Example 4d | 250 | 3.0 | A | A | A | A | A | A | A |
| Comparative | 200 | 0.5 | B | B | B | B | B | C | C |
| Example 1a | | | | | | | | | |
| Comparative | 200 | 3.0 | B | B | B | B | B | C | C |
| Example 1b | | | | | | | | | |
| Comparative | 250 | 0.5 | B | B | B | B | B | B | C |
| Example 1c | | | | | | | | | |
| Comparative | 250 | 3.0 | B | B | B | B | B | B | C |
| Example 1d | | | | | | | | | |

### <Evaluation of Heat Resistance>

The heat resistance of the wiring boards according to Examples 1a to 4d and Comparative Examples 1a to 2d was evaluated. For 5 wirings with L/S of 20 μm/20 μm, 15 μm/15 μm, 10 μm/10 μm, 7 μm/7 μm, 5 μm/5 μm, 3 μm/3 μm, and 2 μm/2 μm, a test was performed by using a HAST chamber (EHS-222MD, manufactured by ESPEC CORP.) at a retention temperature of 130° C., a relative humidity of 85%, and a retention time of 500 hours. After the heat resistance test, a wiring cross-section was observed with a scanning electron microscope (manufactured by Hitachi High-Tech Corporation, Regulus 8230), and the film thickness of copper oxide (CuO) on the wiring surface and the presence or absence of detachment of the wiring and the insulating material were observed. A case in which the thickness of copper oxide (CuO) was 50 nm or less was rated as “A”; a case in which the thickness was 80 nm or less was rated as “B”; and a case in which the thickness was 150 nm or less was rated as “C”. The evaluation results for the thickness of copper oxide are presented in Table 4. After the heat resistance test, among ten wirings, a case in which the number of wirings without detachment was rated as “A”; a case in which the number was 7 or more was rated as “B”; and a case in which the number was 5 or more was rated as “C”. The evaluation results for detachment are presented in Table 5.

TABLE 4

| | Heating | Heating | Evaluation of thickness of | | | | | | |
|---|---|---|---|---|---|---|---|---|---|
| | Temperature | Time | copper oxide (CuO) L/S(μm/μm) | | | | | | |
| | (° C.) | (h) | 20/20 | 15/15 | 10/10 | 7/7 | 5/5 | 3/3 | 2/2 |
| Example 1a | 200 | 0.5 | A | A | A | A | A | A | A |
| Example 1b | 200 | 3.0 | A | A | A | A | A | A | A |
| Example 1c | 250 | 0.5 | A | A | A | A | A | A | A |
| Example 1d | 250 | 3.0 | A | A | A | A | A | A | A |
| Example 2a | 200 | 0.5 | A | A | A | A | A | A | A |
| Example 2b | 200 | 3.0 | A | A | A | A | A | A | A |
| Example 2c | 250 | 0.5 | A | A | A | A | A | A | A |
| Example 2d | 250 | 3.0 | A | A | A | A | A | A | A |
| Example 3a | 200 | 0.5 | A | A | A | A | A | A | A |
| Example 3b | 200 | 3.0 | A | A | A | A | A | A | A |
| Example 3c | 250 | 0.5 | A | A | A | A | A | A | A |
| Example 3d | 250 | 3.0 | A | A | A | A | A | A | A |
| Example 4a | 200 | 0.5 | A | A | A | A | A | A | A |
| Example 4b | 200 | 3.0 | A | A | A | A | A | A | A |
| Example 4c | 250 | 0.5 | A | A | A | A | A | A | A |
| Example 4d | 250 | 3.0 | A | A | A | A | A | A | A |
| Comparative | 200 | 0.5 | B | B | B | B | B | B | B |
| Example 1a | | | | | | | | | |
| Comparative | 200 | 3.0 | B | B | B | B | B | B | B |
| Example 1b | | | | | | | | | |
| Comparative | 250 | 0.5 | C | C | C | C | C | C | C |
| Example 1c | | | | | | | | | |
| Comparative | 250 | 3.0 | C | C | C | C | C | C | C |
| Example 1d | | | | | | | | | |

TABLE 5

| | Heating | Heating | | | | | | | |
|---|---|---|---|---|---|---|---|---|---|
| | Temperature | Time | Evaluation of detachment L/S(μm/μm) | | | | | | |
| | (° C.) | (h) | 20/20 | 15/15 | 10/10 | 7/7 | 5/5 | 3/3 | 2/2 |
| Example 1a | 200 | 0.5 | A | A | A | A | A | A | A |
| Example 1b | 200 | 3.0 | A | A | A | A | A | A | A |
| Example 1c | 250 | 0.5 | A | A | A | A | A | A | A |
| Example 1d | 250 | 3.0 | A | A | A | A | A | A | A |
| Example 2a | 200 | 0.5 | A | A | A | A | A | A | A |
| Example 2b | 200 | 3.0 | A | A | A | A | A | A | A |
| Example 2c | 250 | 0.5 | A | A | A | A | A | A | A |
| Example 2d | 250 | 3.0 | A | A | A | A | A | A | A |
| Example 3a | 200 | 0.5 | A | A | A | A | A | A | A |
| Example 3b | 200 | 3.0 | A | A | A | A | A | A | A |
| Example 3c | 250 | 0.5 | A | A | A | A | A | A | A |
| Example 3d | 250 | 3.0 | A | A | A | A | A | A | A |
| Example 4a | 200 | 0.5 | A | A | A | A | A | A | A |
| Example 4b | 200 | 3.0 | A | A | A | A | A | A | A |
| Example 4c | 250 | 0.5 | A | A | A | A | A | A | A |
| Example 4d | 250 | 3.0 | A | A | A | A | A | A | A |
| Comparative | 200 | 0.5 | B | B | B | B | B | B | B |
| Example 1a | | | | | | | | | |
| Comparative | 200 | 3.0 | B | B | B | B | B | B | B |
| Example 1b | | | | | | | | | |
| Comparative | 250 | 0.5 | C | C | C | C | C | C | C |
| Example 1c | | | | | | | | | |
| Comparative | 250 | 3.0 | C | C | C | C | C | C | C |
| Example 1d | | | | | | | | | |

### INDUSTRIAL APPLICABILITY

According to the present disclosure, there is provided a method for producing a wiring board in which a wiring part and an insulating material layer have sufficient adhesiveness and heat resistance and also having sufficient insulation reliability.

### REFERENCE SIGNS LIST

1: first insulating material layer, 2: second insulating material layer, 3: third insulating material layer, 5: surface-treated layer, 6: surface treatment agent-removed part, 7: calcined layer, 8A, 8B: wiring layer, 10, 20, 30: wiring board, 40: multilayer wiring board, C: wiring part, C1: pad, C2: wiring, F: desmear-treated surface, H: opening, H1: first opening part, H2: second opening part, R: resist pattern, R1, R2: opening part, S: supporting substrate, Sa: conductive layer, T: seed layer.

1. A method for producing a wiring board, the method comprising steps of:
(A) forming a first insulating material layer on a supporting substrate;
(B) forming a first opening part in the first insulating material layer;
(C) forming a seed layer on a surface of the first insulating material layer by electroless plating;
(D) providing a resist pattern for wiring part formation on a surface of the seed layer;
(E) forming a wiring part including a pad and wiring by electrolytic plating in a region exposed from the resist pattern on the surface of the seed layer;
(F) removing the resist pattern;
(G) removing the exposed seed layer by removal of the resist pattern;
(H) applying a first surface treatment to a surface of the pad;
(I) forming a second insulating material layer so as to cover the wiring part;
(J) forming a second opening part at a position corresponding to the pad in the second insulating material layer;
(K) applying a second surface treatment to the surface of the pad; and
(L) heating the second insulating material layer to a temperature equal to or higher than a glass transition temperature of the second insulating material layer.

2. The method for producing a wiring board according to claim 1, wherein a surface treatment agent is used in the step of applying the first surface treatment, and the surface treatment agent is removed from the surface of the pad in the step of applying the second surface treatment.

3. The method for producing a wiring board according to claim 2, wherein the surface treatment agent used for the first surface treatment includes an organic component for improving an adhesiveness between the wiring part and the second insulating material layer.

4. The method for producing a wiring board according to claim 1, wherein the second surface treatment is at least one selected from the group consisting of an oxygen plasma treatment, an argon plasma treatment, and a desmear treatment.

5. The method for producing a wiring board according to claim 1, wherein an average roughness Ra of a surface of the wiring part that has been subjected to the first surface treatment is 40 to 80 nm.

6. The method for producing a wiring board according to claim 1, wherein after step (J), a peel strength of the second insulating material layer is 0.2 to 0.7 kN/m with respect to the wiring.

7. The method for producing a wiring board according to claim 1, further comprising a step of removing residue on the first insulating material layer and/or inside the first opening part, between step (B) and step (C).

8. The method for producing a wiring board according to claim 1, wherein at least one of the first insulating material layer and the second insulating material layer includes a photosensitive resin.

9. The method for producing a wiring board according to claim 11 wherein the resist pattern has a groove-shaped opening having a line width of 0.5 to 20 μm.
